(19) United States
(12) Patent Application Publication
(10) Pub. No.: US 2025/0385065 A1
(43) Pub. Date: Dec. 18, 2025

(54) Charged Particle Source, Charged Particle Gun, and Charged Particle Beam Device

(71) Applicant: Hitachi High-Tech Corporation, Minato-ku, Tokyo (JP)

(72) Inventors: Yuki JOKOJI, Tokyo (JP); Masahiro FUKUTA, Tokyo (JP); Masayuki FUKUMOTO, Tokyo (JP)

(21) Appl. No.: 18/878,789

(22) PCT Filed: Jul. 20, 2022
(86) PCT No.: PCT/JP2022/028263

§ 371 Date: Dec. 24, 2024

(51) Int. Cl. H01J 37/073; H01J 37/28

(52) U.S. Cl. CPC H01J 37/073; H01J 37/28

(57) ABSTRACT

The purpose of the present disclosure is to stabilize the probe current of a charged particle source over long periods of time. In a charged particle source according to the present disclosure, an emitter tip has a first flat surface perpendicular to an optical axis, a plurality of second flat surfaces parallel to the optical axis, and a plurality of third flat surfaces each disposed between the first flat surface and a second flat surface. Among the plurality of second flat surfaces, a first distance between second flat surfaces located at positions facing each other across the optical axis is greater than the outer diameter of the boundary portion between the tip and a needle.

### TECHNICAL FIELD

The present invention relates to a charged particle source that emits charged particles.

### BACKGROUND ART

An electron source is an example of a charged particle source. The electron source is mounted on an electron gun of an electron beam application apparatus including a scanning electron microscope (SEM). An electron beam is emitted from a tip end of the electron source. An energy difference between a vacuum level and a metal Fermi level of the electron source is energy required for an electron to escape from a surface of the electron source, and is called a work function. When an electron on the surface of the electron source obtains energy to exceed the work function, the electron is emitted from the surface of the electron source.

There are a plurality of methods for emitting electrons, including a thermal electron source that accelerates and emits electrons excited by heating and a field emission electron source that emits electrons by a tunnel effect due to an action of an electric field. Since the thermal electron source is generated by heating an electron source to a high temperature, surrounding gas molecules are difficult to be adsorbed. Accordingly, a layer of other molecules is not formed on the surface of the electron source, so that the work function on the surface of the electron source is constant, and an emitted current has high stability. Therefore, the thermal electron source can also be used in a low vacuum in which an operating atmosphere is about 10⁻³ Pa. However, in the case of the thermal electron source, the emitted electrons have a large variation in energy. Electron emission with high energy dispersion causes a large chromatic aberration generated when electrons pass through a lens, which is a cause of low spatial resolution in an SEM optical system. On the other hand, the field emission electron source has a feature that energy dispersion of the emitted electrons is low. Accordingly, luminance increases, which contributes to high spatial resolution of the SEM. However, since the field emission electron source is generally used at room temperature or lower, the work function changes and an electron emission amount fluctuates due to adsorption of surrounding gas.

In this manner, main parameters of the electron emission include a temperature of the electron source and an electric field intensity at the tip end of the electron source. Among the electron sources, there is a thermal field emission electron source (Schottky electron source) using both heat and an electric field, which is to be used as an electron source capable of achieving both current stability after electron emission and high spatial resolution.

With the SEM, a nano-order fine structure can be imaged and observed using an electron beam that passes through a plurality of apertures to irradiate a sample after electrons are emitted from the electron source. This electron beam is called a probe current. The SEM has high spatial resolution and is thus applied to an inspection in a semiconductor device manufacturing process. Representative examples of the inspection include a pattern defect inspection, and it is desirable that contrast or brightness of an observation image is constant in order to perform an accurate defect inspection. When the amount of probe current changes for each observation image, the brightness of the image changes, which makes it difficult to automatically determine a defect. In this manner, a continuous operation using a probe current stable over a long time is required for a semiconductor device inspection. In recent years, with high integration of semiconductor patterns, it is necessary to perform observation with high throughput using a large current probe.

Although the Schottky electron source has excellent stability, the amount of probe current fluctuates and is in an unstable state due to a change in surface state depending on a vacuum environment or electron source using conditions (a temperature of the electron source and an electric field intensity) during such an operation over a long time.

Related-art patent literatures related to the present application focus on a fact that a shape of an electron source greatly contributes to an electric field acting on the electron source. Hereinafter, objects and characteristics of the related-art patent literatures will be introduced.

In a semiconductor device inspection apparatus, it is necessary to reduce a light source diameter in order to achieve high spatial resolution. The light source diameter is a radius of a light source at a position of an object surface when a radius of a probe current used for irradiation is set to a size of an image in an SEM optical system. With the same amount of current, a smaller radius of the light source results in higher luminance and higher spatial resolution. Since a small-current probe current has low energy dispersion of electrons, an increase in the light source diameter due to a chromatic aberration can be reduced. However, an overall shape of the Schottky electron source changes during an operation over a long time, and thus the electric field intensity continuously changes. Accordingly, an emission current is reduced, and the luminance changes.

PTL 1 aims to solve the problem in current stability and proposes the following shape of the electron source. A charged particle source including a thermal electron source in PTL 1 has an emission facet serving as a surface for emitting the most electrons, and a first side facet and a second side facet that are adjacent to the emission facet. An edge facet is formed between the first side facet and the second side facet. A width of the edge facet is 20% to 40% of a width of the emission facet.

This shape can be expected to have an effect of maintaining the shape even under an operating condition in which a low electric field is applied under a small-current probe current. However, as described above, there is also a strong demand for a high-throughput inspection using a large-current probe current, which needs to be balanced with high spatial resolution. When an electron source is used at a high temperature and a high electric field in order to use a large current, an increase in the light source diameter due to a chromatic aberration is dominant. As another method, the probe current can be increased by adjusting an optical magnification. This expands capturing of emitted electrons that pass through an aperture from the vicinity of an optic axis orthogonal to a center of the emission facet to an off-axis portion.

The charged particle source in PTL 1 has a needle shape as a whole, and it is considered that a tip end portion described in drawings of PTL 1 is formed at a tip end of a needle. The shape of the tip end portion described in PTL 1 is formed such that an end portion of a side facet 113 is adjacent to a side surface of the needle portion. In this manner, when the tip end portion is sharply transformed from the facet to the needle shape, an equipotential surface is more distorted as the emitted electrons deviate from the optic axis. Accordingly, energy dispersion increases, which causes an increase in the light source diameter.

PTL 2 aims to provide a charged particle source having a small light source diameter with low energy dispersion of emitted electrons even under a condition of a large-current probe current. As described above, in the case of obtaining a large current, the energy dispersion increases and the light source diameter increases. According to the technique described in PTL 2, an electric field acting on a surface of a tip end of an electron source is made uniform over a wide range, so that it is possible to reduce the energy dispersion when a large current is captured.

Therefore, when the tip end of the electron source has a spherical surface as in PTL 2, since equipotential lines near the tip end of the electron source also form a spherical surface, the energy dispersion of the emitted electrons can be reduced to a maximum limit in calculation. However, an actual spherical surface is formed of a large number of steps, which contributes to current unstability.

### CITATION LIST

### Patent Literature

PTL 1: JP2017-157558A

PTL 2: WO2020/115825A1

### SUMMARY OF INVENTION

### Technical Problem

Atoms constituting the Schottky electron source are moved by free energy due to heating. Accordingly, the diameter increases such that the tip end of the needle-shaped electron source is rounded. The movement of the atoms is defined as diffusion.

In particular, when tip ends of electron sources having the same diameter are compared, a nearly spherical shape results in higher free energy, and diffusion of atoms constituting the electron source is likely to occur. Accordingly, a shape of a {100} plane, which is an electron emission surface, changes over time on a crystal plane at the very tip end of the electron source.

As in the charged particle source in PTL 2, when the diameter is large and the surface of the tip end has a nearly spherical shape, the {100} plane tends to have a stepped shape with two or more steps. The steps collapse from an end of the {100} plane due to the above-described diffusion, and move toward the center. The movement of the steps and the diffusion of atoms change depending on a balance between the temperature of the electron source and the electric field intensity acting on the tip end of the electron source for extracting electrons.

A step portion of the electron source is formed by a plane other than the {100} plane, which is an electron emission surface, and electrons are difficult to be emitted. Since the step moves in the {100} plane at the tip end, the amount of probe current is unstable every time the probe current passes through the step. Due to these influences, the radius of the tip end of the electron source increases over a long time, and the electric field intensity changes due to a change in shape. Accordingly, since the diffusion continues to occur in the tip end of the electron source, the probe current is considered to be consistently unstable.

When the shape of the tip end of the electron source is close to a spherical surface, high spatial resolution can be expected, but it is very difficult to maintain a balance between heat and an electric field, and there is a possibility that the probe current is periodically unstable. In an electron source applied for inspection or length measurement in a scanning electron microscope or the like, an electron emission amount from the {100} plane at the tip end is required to be stable over a long time.

In view of the above problem, an object of the invention is to stabilize a probe current of a charged particle source over a long time.

### Solution to Problem

In a charged particle source according to the invention, a tip end portion of an emitter has a first flat surface perpendicular to an optic axis, a plurality of second flat surfaces parallel to the optic axis, and a plurality of third flat surfaces arranged between the first flat surface and the second flat surfaces. A first distance between the second flat surfaces located at positions facing each other via the optic axis among the plurality of second flat surfaces is larger than an outer diameter of a boundary portion between the tip end portion and the needle portion.

Advantageous Effects of Invention

The charged particle source according to the invention can easily maintain a stable shape. The shape of the {100} plane is stabilized similarly to the tip end even on four side surfaces, and the shape of the tip end can be maintained more firmly.

### BRIEF DESCRIPTION OF DRAWINGS

FIG. 1 illustrates an overall view of an electron source according to Embodiment 1.

FIG. 2 is an enlarged view near a tip end of a needle portion 101 of the electron source.

FIG. 3 is an enlarged view of a shape of a tip end of a charged particle source according to Embodiment 2.

FIG. 4 illustrates deformation of the tip end of the electron source due to diffusion of tungsten atoms.

FIG. 5 is an enlarged view of a shape of a tip end of a charged particle source according to Embodiment 3.

FIG. 6 is a configuration diagram of a charged particle beam apparatus 600 according to Embodiment 4.

FIG. 7 is a configuration diagram of a charged particle beam apparatus according to Embodiment 5.

### DESCRIPTION OF EMBODIMENTS

### Embodiment 1: Basic Principle

Hereinafter, a basic principle according to an embodiment of the invention will be described first, and then a specific configuration according to the embodiment will be described. A radius of an electron source is defined as r, and a radius of the electron source that increases per unit time by diffusion due to heating is defined as dr/dt. If a temporal change of the radius, when an electric field acts on the electron source in addition to heating, is defined as (dr/dt)_{F}, a relationship can be expressed by the following formula. In the formula, F refers to an electric field applied to a tip end of the electron source, and ν refers to a surface tension acting on a surface of the electron source: (dr/dt)_{F}=(1−F²/8πν)dr/dt.

By applying an electric field equal to or greater than F with which (1−F²/8πν)=0, deformation due to diffusion can be reduced. When a shape of the tip end is a spherical surface, there is an advantage that a uniform electric field can act in a wide range. However, when electrons are emitted under a condition in which a balance is broken, diffusion occurs over the entire tip end of the electron source.

In order not to change a curvature of the tip end of the electron source in a range as wide as possible, a shape of a tip end having a constriction and being close to a sphere is effective. Accordingly, a curvature of the very tip end related to a probe current can be made constant. The shape of the tip end can be maintained over a long time by having a portion where the curvature changes locally rather than being a complete sphere.

Therefore, a charged particle source according to the invention has a constriction near a needle-shaped tip end, which is made of single-crystal tungsten or the like, and has a tip end portion in a polyhedral shape from the constriction to the tip. This polyhedron has a {100} plane on all of an upper surface and four side surfaces. The polyhedron has, with the {100} plane on the upper surface serving as a center, a sloped surface having a {110} plane inclined at 45° from the upper surface between the {100} plane on the upper surface and the {100} plane on the side surface. Accordingly, the periphery of the {100} plane can be locally set as a strong electric field, and it is possible to be closer to (1−F²/8πν)=0. In addition, since the shape of the tip end has the constriction and is close to a regular polyhedron, the four side surfaces also have a shape similar to the tip end, and similar crystal growth is observed in all directions. That is, the above effect can be obtained by providing a charged particle source in which a bottom surface and the side surfaces of the tip end include rotationally symmetric crystal planes.

### Embodiment 1: Configuration of Charged Particle Source

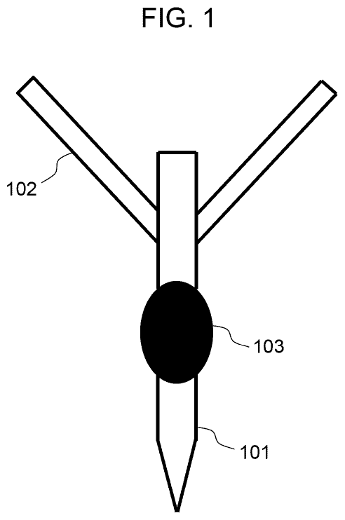

FIG. 1 is an overall view of an electron source according to Embodiment 1 of the invention. In Embodiment 1, a configuration example of a Schottky electron source made of tungsten, which is a representative charged particle source, will be described.

The electron source includes a needle portion 101 that is tapered toward a tip end, a filament portion 102 bent in a V shape, and a zirconia portion 103. The vicinity of a base of the needle portion 101 and the filament portion 102 are fixed to each other by welding. A middle portion of the needle portion 101 is coated with zirconia, and both the needle portion 101 and the zirconia portion 103 are heated by electrically heating the filament portion 102.

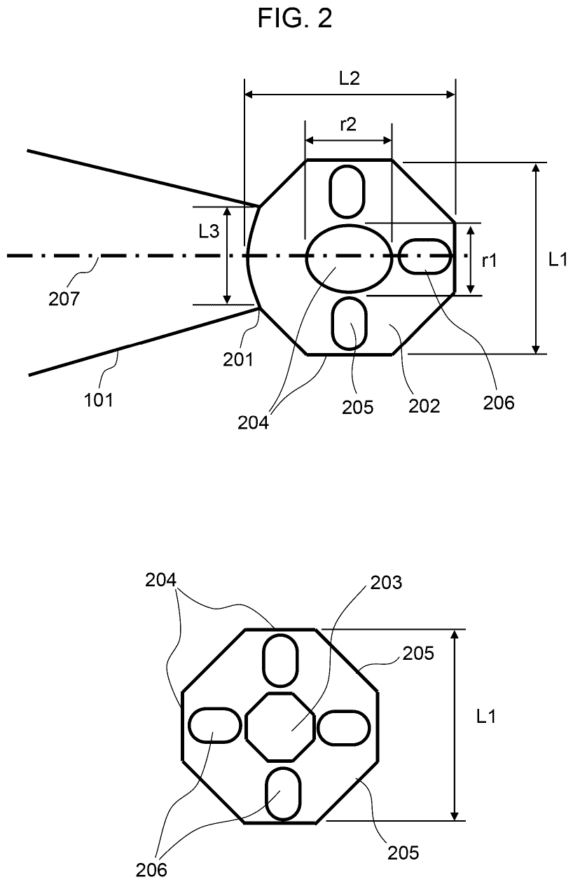

FIG. 2 is an enlarged view near the tip end of the needle portion 101 of the electron source. An upper part in FIG. 2 is a side view, and a lower part in FIG. 2 is a bottom view (a view in which an optic axis of an electron beam is a depth direction). When a central axis of the electron beam emitted from the tip end of the electron source is defined as an optic axis 207, the optic axis 207 is coaxial with the needle portion 101. The needle portion 101 has a constriction portion 201 with widths L1>L3 near the tip end, as illustrated in FIG. 2. The radius of the electron source temporarily increases from the constriction portion 201 toward the tip end. Thereafter, a polyhedral shape having a plurality of flat surfaces is obtained. A portion from the constriction portion 201 to the tip end is defined as a polyhedral portion 202. The constriction portion 201 is provided at a position where spheres intersect with the needle portion 101. The spheres respectively circumscribe a surface perpendicular to the optic axis 207 (a first flat surface 203) and side surfaces parallel to the optic axis 207.

The polyhedral portion 202 has the following surfaces: the first flat surface 203 as a surface perpendicular to the optic axis 207; second flat surfaces 204 and 205 as horizontal surfaces with respect to the optic axis 207; and third flat surfaces 206 between the first flat surface 203 and the second flat surfaces 204. Each of the second flat surfaces includes the {100} plane and the {110} plane that are fourfold symmetrical about the optic axis 207. The second flat surfaces 204 ({ 100} planes) and the second flat surfaces 205 ({ 110} planes) are alternately provided at an interval of 45°. The third flat surfaces 206 are provided between the first flat surface 203 and the second flat surfaces 204 so as to be aligned in a straight line on a surface of the polyhedral portion 202.

The electron source in the present embodiment is obtained by processing a single crystal of tungsten into a needle shape, and an optic axis direction is set as <100>. The second flat surface 204 ({ 100} plane) has a long width in the optic axis direction, and the second flat surface 205 ({ 110} plane) has a short width in the optic axis direction. The third flat surfaces 206 include the {110} plane.

Regarding the second flat surface 204 ({100} plane), when a width in a direction perpendicular to the optic axis 207 is defined as r1 and a width in a direction parallel to the optic axis is defined as r2, r1<r2. When compared with a distance L2 in the optic axis direction from the first flat surface 203 to a position of the constriction portion 201, L2>r2. When a diameter of the constriction portion 201 is L3, L1>L3>r1.

Zirconia diffuses from the zirconia portion 103 in FIG. 1 toward the tip end portion of the electron source to form a mixed layer with tungsten. Accordingly, since a work function of the {100} plane decreases, electrons are emitted from the {100} plane. In particular, the electrons emitted from {100} of the first flat surface 203 are used as a probe current of a scanning electron microscope. In order to stably emit the probe current, the shape of the first flat surface 203 as an electron emission surface needs to be stable.

In tungsten atoms constituting the electron source, a surface tension using heat as a parameter acts, and atoms diffuse in a direction in which the radius increases. Accordingly, the shape changes over time, the electric field intensity and a size of the crystal plane are not constant, and the probe current is unstable. In contrast, the electron source according to the present embodiment has the constriction portion 201, and the constriction side and the tip end side of the polyhedral portion 202 have symmetrical shapes, so that diffusion occurs in an opposite direction in the constriction portion 201. Accordingly, it is considered that there is an effect of reducing a change in dimension L1 of the polyhedron due to the diffusion.

As in the present embodiment, in a crystal structure in which the bottom surface and the side surfaces are rotationally symmetrical, a uniform electric field is easily applied from the first flat surface 203 to the side surfaces as compared with an electron source in which the shape rapidly changes from the electron emission surface to a needle shape when the shape of the tip end is a cone, a pyramid, or the like. Accordingly, it is easy to maintain the shape of the tip end over a long time.

### Embodiment 2

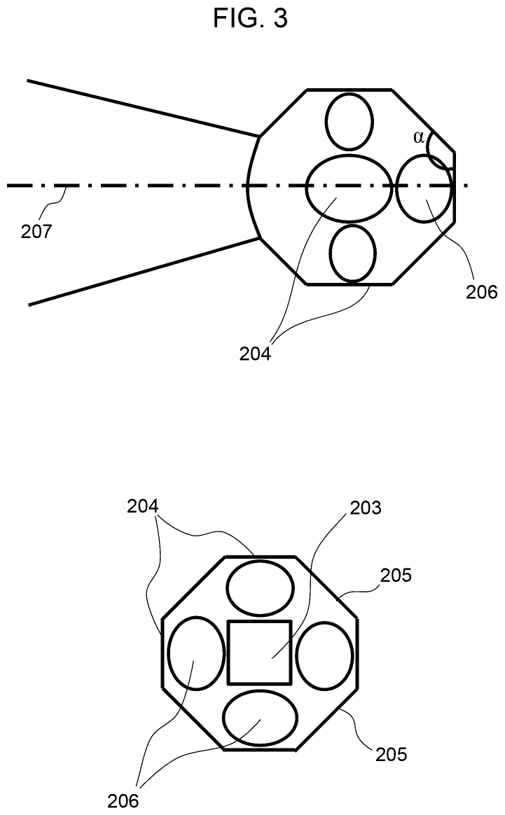

FIG. 3 is an enlarged view of a shape of a tip end of a charged particle source according to Embodiment 2 of the invention. Similar to FIG. 2, an upper part in FIG. 3 is a side view and a lower part in FIG. 3 is a bottom view. The charged particle source according to Embodiment 2 has a feature that the first flat surface 203 has a quadrangular shape in addition to features according to Embodiment 1. When the first flat surface 203 has a quadrangular shape as in FIG. 3, a change in shape due to diffusion can be further reduced as compared with a case of a circular shape.

The diffusion can be expressed by the following formula in terms of free energy on the surface of tungsten atoms: μ=Ω{νκ−(1/2)ε₀F²}. μ is free energy, Ω is a volume of the tungsten atoms, ν is a surface tension, κ is a local curvature, ε₀ is a dielectric constant, and F is an electric field. Due to a gradient of the free energy between adjacent surfaces, atoms diffuse in an orientation from a high-energy potential to a low-energy potential.

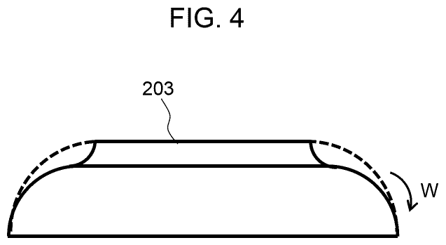

FIG. 4 illustrates deformation of the tip end of the electron source due to diffusion of the tungsten atoms. FIG. 4 is a further enlarged side view of the periphery of the first flat surface 203. When the tungsten atoms diffuse according to the above formula, the tungsten atoms on a surface portion surrounded by dotted lines in FIG. 4 move toward the base along the side surfaces in a manner of moving away from the first flat surface 203. That is, the first flat surface 203 gradually narrows. As a result, a step is generated at an end of first flat surface 203 as in the surface after diffusion indicated by solid lines. Even after the step is generated, the atoms continue to move from an end of the step, and thus the step decreases in size toward the center. A probe current is unstable due to a movement of the step in the first flat surface 203. However, the term (1/2)ε₀F² having an electric field as a parameter is balanced with the term νκ of the surface tension, so that the movement of the atoms can be stopped at that position.

When the first flat surface 203 has a quadrangular shape as in the present embodiment, there are crystal planes adjacent to the first flat surface 203 and constituting four sides of the first flat surface 203. The adjacent surfaces are the third flat surfaces 206 or {112} planes present between the third flat surfaces 206. When an angle formed by each of the four sides of the quadrangle of the first flat surface 203 and an adjacent surface is defined as α (see FIG. 3), since the third flat surface 206 is inclined at 45° with respect to the first flat surface 203 based on the crystal structure, an edge having an angle of α=180°−45°=135° or more is formed. This is an edge portion having a locally small curvature, which causes a reduction in surface tension due to heat and generation of a strong electric field, and approaches a balance direction.

The quadrangular shape of the first flat surface 203 includes, in addition to a strict quadrangular shape, an overall quadrangular shape having rounded corners or sides. It should be noted that actual a includes an individual difference of about ±10° from a calculated value due to distortion of the crystal structure or the like.

### Embodiment 3

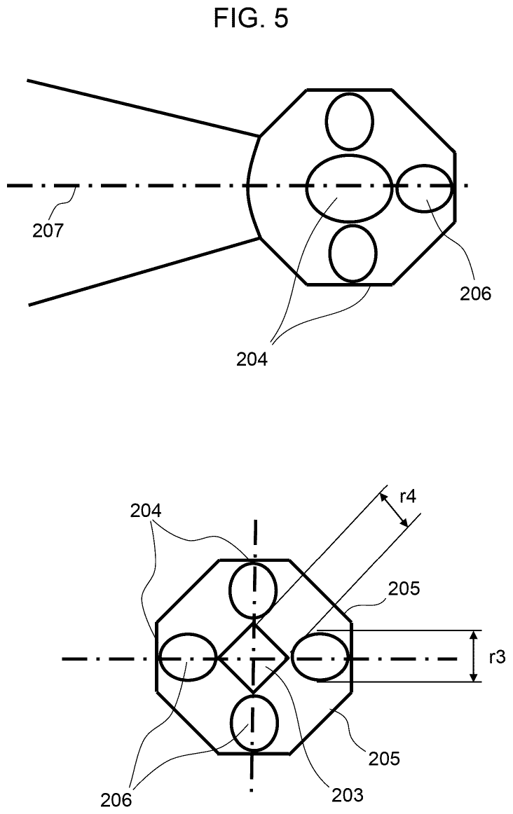

FIG. 5 is an enlarged view of a shape of a tip end of a charged particle source according to Embodiment 3 of the invention. Similar to FIG. 2, an upper part in FIG. 5 is a side view and a lower part in FIG. 5 is a bottom view. Embodiment 3 is a modification of Embodiment 2. A width of the third flat surface 206 is defined as r3, and a width of a region between the third flat surfaces 206 represented by the {112} plane is defined as r4 as in FIG. 5.

The first flat surface 203 is a quadrangle, an orientation of each corner thereof is determined by a ratio between the width r3 of the third flat surface 206 surrounding the first flat surface 203 and an interval r4, and thus corners and sides are arranged by rotating 45°. In the present embodiment, a configuration example is illustrated in which r3≤r4 and the third flat surfaces 206 are arranged in orientations of the corners of the quadrangle (when straight lines connecting a center and the corners of the first flat surface 203 are extended, the straight lines intersect with the third flat surfaces 206).

As illustrated in FIG. 5, a portion corresponding to a corner of the quadrangular of the first flat surface 203 coincides in orientation with the third flat surface 206 that is present on a sloped surface at an interval of 90°. At this time, an angle α of an edge is an obtuse angle as compared with Embodiment 2, and is about 145° or more. As the edge is sharper, a strong electric field acts and concentrates on the edge portion. Accordingly, an electric field intensity concentrates on an outer periphery in a plane of the first flat surface 203, and a difference occurs in the electric field intensity between a paraxial portion and an off-axis portion with respect to the optic axis 207. Accordingly, energy dispersion increases, and a radius of a light source increases due to a chromatic aberration of a lens. This is one of the factors that cause degradation in resolution when the electron source is used in a scanning electron microscope, and should be avoided as performance of the electron source.

In Embodiments 2 and 3, the ratio between the width r3 of the third flat surface 206 and the width r4 of the region between the third flat surfaces including the {112} is not particularly limited. The electric field applied to the edge portion is optimized by changing a ratio of a size of a surface around the first flat surface 203 according to an electron emission condition of the electron source. Accordingly, a stable probe current due to stabilization of the first flat surface 203 and a state in which the energy dispersion of electrons serving as a factor in the chromatic aberration is low can be both achieved.

### Embodiment 4

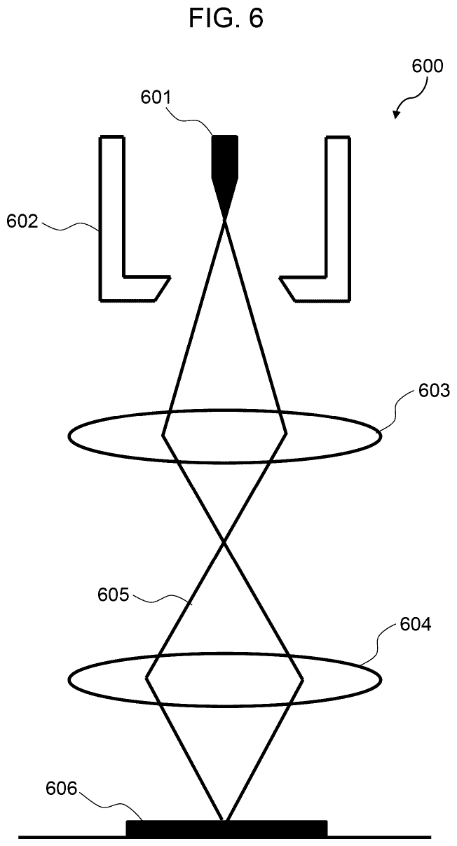

FIG. 6 is a configuration diagram of a charged particle beam apparatus 600 according to Embodiment 4 of the invention. The charged particle beam apparatus 600 is equipped with an electron source 601 according to any one of Embodiments 1 to 3, and can be applied as a scanning electron microscope.

The charged particle beam apparatus 600 includes an extraction electrode 602 in a manner of facing directly below the electron source 601. By applying a voltage to the extraction electrode 602, electrons are extracted from the electron source 601. The electron source 601 and the extraction electrode 602 can form an electron gun (charged particle gun). The charged particle beam apparatus 600 includes a condenser lens 603 in a middle stage, through which an electron beam 605 passes and is focused. The condenser lens 603 adjusts the amount of current of the emitted electron beam 605. The charged particle beam apparatus 600 includes an objective lens 604 in a lower stage, which focuses the electron beam 605 onto a sample 606.

### Embodiment 5

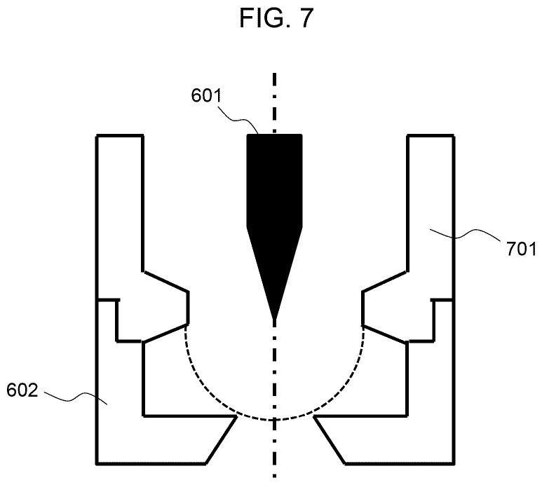

FIG. 7 is a configuration diagram of a charged particle beam apparatus according to Embodiment 5 of the invention. FIG. 7 illustrates a periphery of the electron source 601. In the present embodiment, in addition to the configuration described in Embodiment 4, an auxiliary electrode 701 is added between the electron source 601 and the extraction electrode 602 in order to make a shape of a tip end of the electron source 601 uniform. Other configurations are the same as those in Embodiment 4.

In order to maintain the shape of the tip end of the electron source 601, it is necessary to balance an electric field and a surface tension based on a temperature. The electron source 601 has a polyhedral shape with a constriction, and it is necessary to maintain not only the shape in an axial direction but also in a direction of a side surface. Since the second flat surface 204 emits a large number of electrons similarly to the first flat surface 203, it is necessary to make the acting electric field uniform. However, the electric field acting on the electron source by the extraction electrode 602 is weaker as a distance from the extraction electrode 602 increases in an order of the first flat surface 203, the third flat surface 206, and the second flat surface 204. Therefore, in the present embodiment, the auxiliary electrode 701 that applies an electric field from the second flat surface 204 away from the extraction electrode 602 to the constriction portion 201 is provided.

The auxiliary electrode 701 has a structure combined with the extraction electrode 602, and is electrically equipotential with an extraction voltage. In order to reduce a variation in the electric field acting on a base of the polyhedral portion 202 at the tip end of the electron source, the auxiliary electrode 701 is provided at a root side of the tip end. Further, in order to make the electric field uniform, end portions of the extraction electrode 602 and the auxiliary electrode 701 are provided on a spherical surface centered on the tip end of the electron source. Accordingly, a uniform extraction voltage can be applied to the entire tip end of the electron source. Since the bottom surface and the side surfaces are symmetrical due to that the shape of the electron source 601 has the constriction according to Embodiments 1 to 3, an effect of maintaining the shape of the electron source can be obtained by the effect of making the electric field uniform.

The present embodiment includes a case where the extraction electrode 602 and the auxiliary electrode 701 are electrically insulated from each other and may also have different potentials. In this case, the auxiliary electrode 701 can be modulated with a voltage different from that of the extraction electrode 602 according to an actual individual difference in the shape of the electron source or the electrode. Feedback is provided for control of the voltage applied to the auxiliary electrode 701 according to the amount of current flowing through each electrode, particularly the amount of current emitted from the second flat surface 204 ({ 100} plane). Accordingly, it is possible to obtain a uniform electric field centered on the tip end of the electron source, which cannot be adjusted by a single electrode.

### Regarding Modification of Invention

Although the electron source has been described as an example of the charged particle source in the above embodiments, the same effect can be obtained by using the invention for another charged particle source such as an ion source that generates ions. The invention is not limited to the embodiments described above, and includes various modifications. For example, a material corresponding to the zirconia portion of the electron source is not limited to Zr, and also includes materials such as Ti, Sc, and Ba.

As an application example of the charged particle beam apparatus according to the invention, the charged particle source according to the invention can be used not only for the scanning electron microscope as in Embodiment 4 but also for a focused ion beam apparatus or an electron beam lithography apparatus.

### REFERENCE SIGNS LIST

101: needle portion
102: filament portion
103: zirconia portion
201: constriction portion
202: polyhedral portion
203: first flat surface
204: second flat surface ({ 100} plane)
205: second flat surface ({ 110} plane)
206: third flat surface
207: optic axis
601: electron source
602: extraction electrode
603: condenser lens
604: objective lens
605: electron beam
606: sample
701: auxiliary electrode

1. A charged particle source comprising:
an emitter configured to emit a charged particle from a tip end, wherein
the emitter includes a tip end portion and a needle portion having a shape tapered toward the tip end portion,
the tip end portion has
a first flat surface perpendicular to an optic axis that is coincident with a crystal axis of the charged particle source in a longitudinal direction,
a plurality of second flat surfaces parallel to the optic axis, and
a plurality of third flat surfaces arranged between the first flat surface and the second flat surfaces,
the plurality of third flat surfaces are arranged in a plane different from any of a plane parallel to the first flat surface, a plane perpendicular to the first flat surface, a plane parallel to the second flat surfaces, and a plane perpendicular to the second flat surfaces, and
a first distance between the second flat surfaces located at positions facing each other via the optic axis among the plurality of second flat surfaces is larger than an outer diameter of a boundary portion between the tip end portion and the needle portion.

2. The charged particle source according to claim 1, wherein
when a plane having a normal line in a direction in which the optic axis extends is defined as a {100} plane, the first flat surface is the {100} plane.

3. The charged particle source according to claim 1, wherein
when a plane having a normal line in a direction in which the optic axis extends is defined as a {100} plane, the plurality of second flat surfaces include the {100} plane and a {110} plane.

4. The charged particle source according to claim 1, wherein
when a plane having a normal line in a direction in which the optic axis extends is defined as a {100} plane, each of the third flat surfaces is a {110} plane.

5. The charged particle source according to claim 3, wherein
the second flat surfaces including the {100} plane have a maximum size in the direction in which the optic axis extends larger than a maximum size in a direction orthogonal to the optic axis.

6. The charged particle source according to claim 3, wherein
the plurality of second flat surfaces include four {100} planes and four {110} planes.

7. The charged particle source according to claim 4, wherein
the third flat surfaces include four {110} planes.

8. The charged particle source according to claim 1, wherein
the first flat surface has a quadrangular shape.

9. The charged particle source according to claim 8, wherein
when the third flat surfaces are projected onto a plane including the first flat surface, the third flat surfaces in a number of four are arranged on four straight lines respectively connecting a center and four corners of the first flat surface.

10. The charged particle source according to claim 1, wherein
the emitter is made of a single crystal of tungsten, and
the needle portion is coated with zirconia.

11. A charged particle gun comprising:
the charged particle source according to claim 1; and
an extraction electrode configured to extract the charged particle from the charged particle source by applying an electric field to the charged particle source, wherein
a portion of the extraction electrode closest to the tip end portion is provided on a spherical surface centered on the tip end portion.

12. The charged particle gun according to claim 11, further comprising:
an auxiliary electrode having a portion closest to the tip end portion provided on the spherical surface, wherein
the auxiliary electrode applies an auxiliary electric field to the charged particle source, the auxiliary electric field being used for reducing a variation in an electric field applied by the extraction electrode to the boundary portion between the tip end portion and the needle portion.

13. A charged particle beam apparatus comprising:
the charged particle source according to claim 1.

14. A charged particle beam apparatus comprising:
the charged particle gun according to claim 11.
